(19) United States
(12) Patent Application Publication
(10) Pub. No.: US 2019/0335601 A1
(43) Pub. Date: Oct. 31, 2019

(54) PV STAX - MULTI-FUNCTION JUNCTION MF/J SYSTEM

(71) Applicant: Chuck McCune, (US)

(72) Inventors: Chuck McCune, Albuquerque, NM (US); Maxim K. Rice, Albuquerque, NM (US); Scott Richard Wilson, Corrales, NM (US)

(21) Appl. No.: 16/201,895

(22) Filed: Nov. 27, 2018

Related U.S. Application Data
(63) Continuation of application No. 14/829,589, filed on Aug. 18, 2015, now Pat. No. 10,143,101.
Application No. 14/829,589 is a continuation-in-part of application No. 14/204,395, filed on Mar. 11, 2014, now Pat. No. 9,791,835.
(60) Provisional application No. 62/039,379, filed on Aug. 19, 2014.
(60) Provisional application No. 61/778,048, filed on Mar. 12, 2013.
(60) Provisional application No. 61/819,640, filed on May 5, 2013.

(51) Int. Cl. H05K 7/02; G05B 9/02; H02S 40/32; H01R 24/30; H01R 13/73; H02S 40/34

(52) U.S. Cl. CPC H05K 7/023; G05B 9/02; H02S 40/32; H01R 2105/00; H01R 13/73; H02S 40/34; H01R 24/30

(57) ABSTRACT

A system to provide a multi-function connection capability to contain and provide for stacking, mounting self-registering Multi-Function Junction (MF/J) boxes that contain a multiplicity of control electronics and can be stacked, removed, replaced, and/or upgraded with a minimal of steps or connection processes in order to simplify methods and conserve on or add value, capabilities to materials and electrical/mechanical equipment. The system can be engaged or utilized by any EMS/First Responder/Service Technician, authorized personnel in any field, Contractor, manufacturer, BOS integrator and any assembler of systems that require a multiplicity of interfacing devices to be in proximity, connection or contact to each other.

### CROSS-REFERENCE TO RELATED APPLICATIONS

This application is a continuation of U.S. patent application Ser. No. 14/829,589, which itself is a continuation-in-part of U.S. patent application Ser. No. 14/204,395, (now U.S. Pat. No. 9,791,835) filed on Mar. 11, 2014, entitled “PV Stop Potential Voltage and Hazard Stop System”, which itself claims priority to and the benefit of U.S. Provisional Patent Application No. 61/778,048, filed on Mar. 12, 2013, entitled “Solar PV Safety Switch and Status Indicator System”, and U.S. Provisional Patent Application No. 61/819,640, filed on May 5, 2013, entitled “PV Stop Potential Voltage and Hazard Stop System”. U.S. application Ser. No. 14/829,589 also claims priority to and the benefit of U.S. Provisional Patent Application No. 62/039,379, filed on Aug. 19, 2014, entitled “PV Stax-Multi-Function Junction MF/J System”, and the specifications and claims (if any) thereof are incorporated herein by reference.

### STATEMENT REGARDING FEDERALLY SPONSORED RESEARCH OR DEVELOPMENT

Not Applicable.

### INCORPORATION BY REFERENCE OF MATERIAL SUBMITTED ON COMPACT DISC

Not Applicable.

### COPYRIGHTED MATERIAL

© Chuck McCune. A portion of the disclosure of this patent document contains material that is subject to copyright protection. The owner has no objection to the facsimile reproduction by anyone of the patent document or the patent disclosure, as it appears in the Patent and Trademark Office patent file or records, but otherwise reserves all copyrights whatsoever.

### BACKGROUND OF THE INVENTION

### Field of the Invention (Technical Field)

The present invention relates to devices and methods for manually or automatically controlling assemblies of devices through electronic and electro-mechanical means, to shut down, restart, modify input/output, invert, rectify, optimize, enhance safety, provide format matching of device interlocking and connection interfaces for electro-mechanical function, water proofing, electrical connection junctions, coupling of devices, coupling of industry standard devices by existing and future add-on equipment/devices, rapid plug/unplug (plug and play) devices in field installations and factory parts/device assemblies of power, liquids, or gases to buildings or facilities in case of emergencies, for adding or removing ganged assemblies and equipment, reconfiguration, maintenance and service and for manual or automated control in other situations.

### BACKGROUND ART

The present invention relates to the Solar PV Panel, the Solar electricity industry, Electrical contracting, First Responder Fire/EMS services, Solar PV service technicians, and electrical and fire safety, manufacturing, automation, robotic, conveyor system, public or private utility, wind turbine, mechanical contracting, gas, fuel process piping of air, gas, chemical, any material, any system that would benefit from a fast means of connection for safety switching and safety control electro-mechanical devices or any system that could benefit by a secure fastening, rapid coupling/stacking system for adding micro inverters, Maximum Power Point Tracking (MPPT), Dc to DC converters, optimizers, individual controllers and data logging of equipment and in particular module level control electronics for Solar PV Modules, concentrated Solar PV and Energy Storage/utilization systems.

### BRIEF SUMMARY OF THE INVENTION

Objects, advantages and novel features, and further scope of applicability of the present invention will be set forth in part in the detailed description to follow, taken in conjunction with the accompanying FIGS. 1-5, and in part will become apparent to those skilled in the art upon examination of the following, or may be learned by practice of the invention. The objects and advantages of the invention may be realized and attained by means of the instrumentalities and combinations particularly pointed out in the appended claims.

The present invention provides a system of stackable self-registering, water proof J-box sleeves covers and MF/J boxes to stack or add on a multiplicity of devices and enclosures to an electrical junction box or a MF/J box as described and claimed in the invention.

The inventive device or system provides a mean to add into the MF/J box enclosures, any number of electrical, electro-mechanical or other control devices to provide for modularity or plug and play rapid installation or removal/replacement, upgrading, assembly and disassembly of stacked MF/J boxes and the enclosed devices.

The inventive device or system provides for a multiplicity of connectors, contacts, leads, wiring harnesses, and varying configurations of electro-mechanical devices.

The inventive device or system provides for the control of the devices within the MF/J boxes through a central control panel such as PV Stop, Fire, and Alarm or other control and command generating systems for electrical and mechanical devices.

### BRIEF DESCRIPTION OF THE SEVERAL VIEWS OF THE DRAWINGS

The accompanying drawings FIGS. 1-5 in the attachment, which are incorporated into and form a part of the specification, illustrate one or more embodiments of the present invention and, together with the description, serve to explain the principles of the invention. The drawings are only for the purpose of illustrating one or more preferred embodiments of the invention and are not to be construed as limiting the invention. In the drawings:

1. PV Stax Multi-Function/Junction Base

2. Locking Female Clip Receiver for Male clip (4)

3. PV Stax Multi-Function/Junction Cover

4. Locking Male Clip

5. PV Stax Multi-Function/Junction Cover with Outlet Receptacle

6. PV Stax Multi-Function/Junction Outlet Receptacle

7. PV Stax Multi-Function/Junction Micro-Inverter or DC to DC Converter

8. PV Stax Multi-Function/Junction Micro-Inverter AC Leads

9. DC Leads

10. PV Stax Multi-Function/Junction Micro-Inverter or DC to DC Converter Male Plug

FIG. 1 is a schematic drawing of a PV Stax Multi-Function/Junction Base depicting the MF/J base box 1, configured with Locking Female Clip Receiver 2.

FIG. 2 is a schematic drawing of PV Stax Multi-Function/Junction Cover 3, configured with Locking Male Clip 4.

FIG. 3 is a schematic drawing of an exploded assembly of multiple possible configurations of PV Stax Multi-Function/Junction MF/J System Components depicting a PV Stax Multi-Function/Junction Cover 3, with DC Leads 9, MF/J Micro inverter or DC to DC Converter 7, a PV Stax Multi-Function/Junction Cover 5, with MF/J Outlet Receptacle 6, and a MF/J Base 1.

FIG. 4 is a schematic drawing depicting a PV Stax Multi-Function/Junction MF/J Cover 5, with a MF/J Outlet Receptacle 6.

FIG. 5 is a schematic drawing depicting a PV Stax Multi-Function/Junction Micro-Inverter 7, with AC Leads 8, and MF/J Male Plug 10.

### DETAILED DESCRIPTION OF THE INVENTION

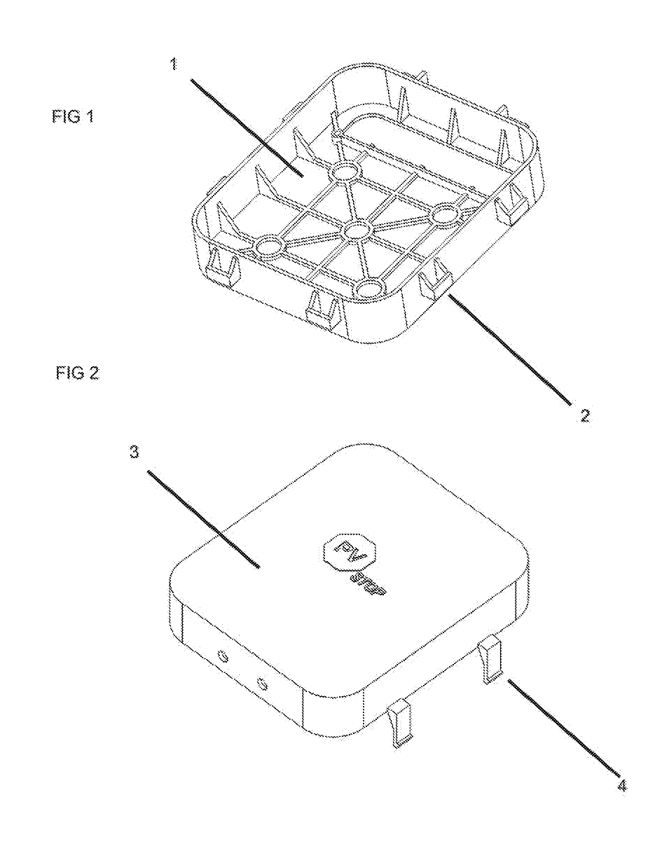

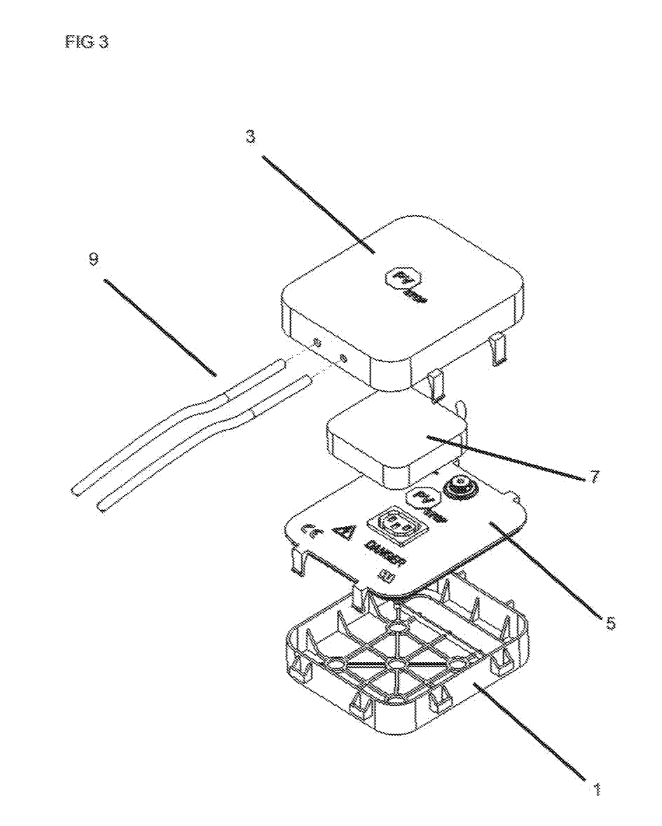

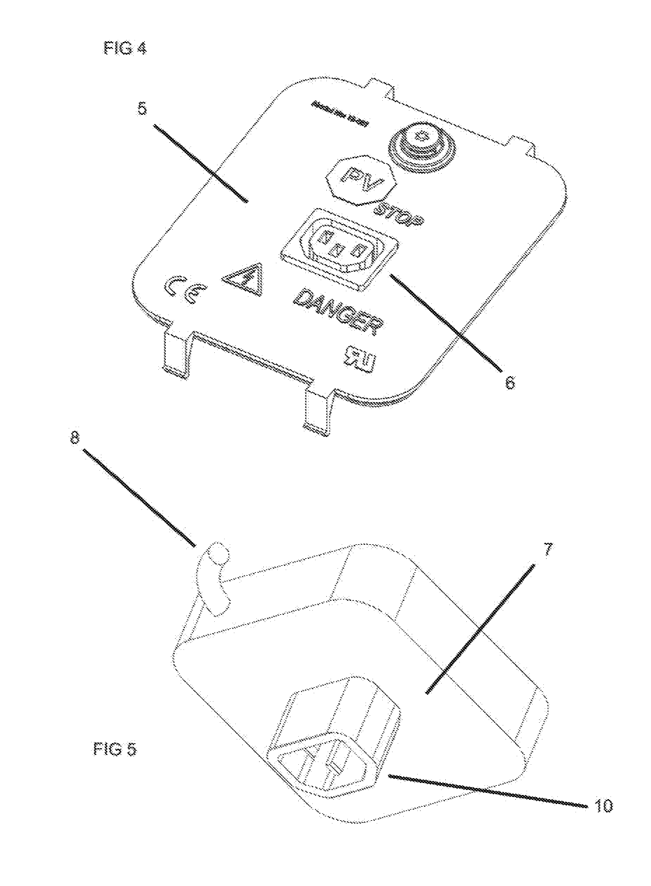

As depicted in FIGS. 1-5 A system to provide a multi-function connection capability to contain and provide for stacking, mounting self-registering Multi-Function Junction (MF/J) boxes that contain a multiplicity of control electronics and can be stacked, removed, replaced, and/or upgraded with a minimal of steps or connection processes in order to simplify methods and conserve on or add value, capabilities to materials and electrical/mechanical equipment. The system can be engaged or utilized by any EMS/First Responder/Service Technician, authorized personnel in any field, Contractor, manufacturer, BOS integrator and any assembler of systems that require a multiplicity of interfacing devices to be in proximity, connection or contact to each other, including Standard Electrical Boxes and enclosures, DC to DC Converters, Micro-Inverters, Module Level Control Electronics, Safety Systems, Monitoring Systems, Rapid Shutdown Systems, Micro Processors and power Semi Conductors. The invention is further described in the documents attached hereto, PV Stax Multi-Function Junction (MF/J) box Drawings pages 1/3, 2/3, 3/3.

### Industrial, Residential and Commercial Applicability

The invention is further illustrated by the following non-limiting examples.

### Example 1

Standard PV J box or MF/J Base box mounted on a PV Module fitted with a MF/J box, containing Diodes, with stackable add on that contains Module Level Control Electronics.

### Example 2

Standard MF/J Module Base J box mounted on a PV Module fitted with a MF/J box add on that contains a DC to DC converter.

### Example 3

Standard MF/J Module J box mounted on a PV Module fitted with a MF/J box add on that contains a Micro Inverter.

### Example 4

Standard MF/J Module Base J box mounted on a PV Module fitted with a MF/J box add on fitted with connections, Diodes and DC leads.

### Example 5

Standard MF/J Module Base J box mounted on an electrical enclosure or utility box of any standard fitted with a MF/J box add on fitted with connections, Diodes and DC leads or AC leads.

What is claimed is:

1. A system comprising:
one or more transmitting and receiving devices, configured to relay and/or switch on from a normally open configuration or off from a normally closed configuration, a source or line supply of hazardous equipment or energized/charged systems in a facility;
a visible and/or audible indicator configured to allow a user to have definitive on or off status of the source or line supply;
said system configured to require a user to overcome an electronic or mechanical lockout apparatus to re-energize the source or line supply; and
a modular control panel comprising:
a communications module, said communications module configured to transmit and receive data to and/or from junction boxes and/or enclosures that are coupled to the one or more transmitting and receiving devices; and
a processor, said processor communicably coupled to one or more front panel peripherals, and/or displays.
